(19) United States
(12) Patent Application Publication
(10) Pub. No.: US 2024/0250499 A1
(43) Pub. Date: Jul. 25, 2024

(54) SEMICONDUCTOR LASER DEVICE, OPTICAL APPARATUS, AND METHOD OF CONTROLLING SEMICONDUCTOR LASER DEVICE

(71) Applicant: Sumitomo Electric Industries, Ltd., Osaka (JP)

(72) Inventor: Daisuke INOUE, Osaka-shi (JP)

(73) Assignee: Sumitomo Electric Industries, Ltd., Osaka (JP)

(21) Appl. No.: 18/402,846

(22) Filed: Jan. 3, 2024

(30) Foreign Application Priority Data
Jan. 19, 2023 (JP) 2023-006770

(51) Int. Cl. H01S 5/062; H01S 5/042; H01S 5/227; H01S 5/50

(52) U.S. Cl. CPC H01S 5/06213; H01S 5/0427; H01S 5/227; H01S 5/50

(57) ABSTRACT

A semiconductor laser device includes a laser region including an active layer and configured to generate light, an amplification region including the active layer and configured to amplify the light, the amplification region being adjacent to the layer region, and an electrode provided to extend over the laser region and the amplification region.

### CROSS REFERENCE TO RELATED APPLICATIONS

This application claims priority based on Japanese Patent Application No. 2023-006770 filed on Jan. 19, 2023, and the entire contents of the Japanese patent application are incorporated herein by reference.

### TECHNICAL FIELD

The present disclosure relates to a semiconductor laser device, an optical apparatus, and a method of controlling a semiconductor laser device.

### BACKGROUND

A semiconductor laser device in which a plurality of devices are integrated is known (for example, PTL 1).
PTL 1: U.S. Patent Application Publication No. 2012/0243074

### SUMMARY

A semiconductor laser device according to the present disclosure is a semiconductor laser device including a laser region including an active layer and configured to generate light; an amplification region including the active layer and configured to amplify the light, the amplification region being adjacent to the layer region; and an electrode provided to extend over the laser region and the amplification region.

### BRIEF DESCRIPTION OF THE DRAWINGS

FIG. 1 is a plan view illustrating an optical apparatus according to a first embodiment.

FIG. 2 is a plan view illustrating a semiconductor laser device.

FIG. 3 is a cross-sectional view taken along line A-A of FIG. 2.

FIG. 4A is a cross-sectional view taken along line B-B of FIG. 2.

FIG. 4B is a cross-sectional view taken along line C-C of FIG. 2.

FIG. 4C is a cross-sectional view taken along line D-D of FIG. 2.

FIG. 5 is a flow chart illustrating a method of controlling a semiconductor laser device.

FIG. 6 is a plan view illustrating a semiconductor laser device according to a comparative example.

FIG. 7A is a diagram illustrating current.

FIG. 7B is a diagram illustrating optical output.

FIG. 7C is a diagram illustrating power efficiency.

FIG. 8A is a diagram illustrating current.

FIG. 8B is a diagram illustrating optical output.

FIG. 8C is a diagram illustrating power efficiency.

FIG. 9A is a diagram illustrating current.

FIG. 9B is a diagram illustrating optical output.

FIG. 9C is a diagram illustrating power efficiency.

FIG. 10A is a diagram illustrating current.

FIG. 10B is a diagram illustrating optical output.

FIG. 10C is a diagram illustrating power efficiency.

FIG. 11A is a diagram illustrating current.

FIG. 11B is a diagram illustrating optical output.

FIG. 11C is a diagram illustrating power efficiency.

FIG. 12A is a diagram illustrating current.

FIG. 12B is a diagram illustrating optical output.

FIG. 12C is a diagram illustrating power efficiency.

FIG. 13A is a diagram illustrating current.

FIG. 13B is a diagram illustrating optical output.

FIG. 13C is a diagram illustrating power efficiency.

FIG. 14A is a diagram illustrating current.

FIG. 14B is a diagram illustrating optical output.

FIG. 14C is a diagram illustrating power efficiency.

FIG. 15 is a plan view illustrating a semiconductor laser device according to a second embodiment.

FIG. 16 is a plan view illustrating a semiconductor laser device according to a third embodiment.

### DETAILED DESCRIPTION

For example, a region functioning as a distributed feedback (DFB) laser and a region functioning as a semiconductor optical amplifier (SOA) are integrated into one device. The electrode of the DFB laser region is separated from the electrode of the SOA region. Since no current is injected into the semiconductor layer located between the electrodes, the semiconductor layer easily absorbs light. As light is absorbed, the loss of light increases. By reducing the distance between the electrodes, the loss of light can be reduced. However, the insulation resistance between the electrodes decreases and the leakage current increases. It is an object to provide a semiconductor laser device, an optical apparatus, and a method of controlling a semiconductor laser device, which are capable of reducing the absorption of light and the leakage current.

### DESCRIPTION OF EMBODIMENTS OF PRESENT DISCLOSURE

First, the contents of embodiments of the present disclosure will be listed and explained.
(1) A semiconductor laser device according to one embodiment of the present disclosure includes a laser region including an active layer and configured to generate light; an amplification region including the active layer and configured to amplify the light, the amplification region being adjacent to the laser region; and an electrode provided to extend over the laser region and the amplification region. A voltage is applied to the laser region and the amplification region using the electrodes to inject current. Since the electrode covers the active layer of the laser region and the amplification region, the absorption of light by the active layer can be reduced. Since the electrodes are provided in the laser region and the amplification region, the leakage current can be reduced.
(2) In (1), the semiconductor laser device may include a first cladding layer, an active layer, and a second cladding layer, the first cladding layer, the active layer, and the second cladding layer may be stacked in this order and may form a mesa in the laser region and the amplification region, and a width of the mesa in the amplification region may be larger than or equal to a width of the mesa in the laser region. Electrical resistance is determined in accordance with the width of the mesa. By adjusting the width of the mesa for each region, the electrical resistance can be controlled, and the current flowing through the laser region and the current flowing through the amplification region can be set to appropriate magnitudes.
(3) In (1) or (2), the amplification region may include a first amplification region and a second amplification region, the laser region and the first amplification region may be adjacent to each other, the first amplification region and the second amplification region may be adjacent to each other, and the electrode may be provided in the laser region, the first amplification region, and the second amplification region. The absorption of light and the leakage current can be reduced.
(4) In (3), a width of the mesa in the second amplification region may be larger than or equal to a width of the mesa in the first amplification region, and the width of the mesa in the first amplification region may be larger than or equal to a width of the mesa in the laser region. The current flowing through the laser region, the current flowing through the first amplification region, and the current flowing through the second amplification region can be set to appropriate magnitudes.
(5) In (3) or (4), a length of the second amplification region may be larger than or equal to a length of the first amplification region and may be larger than or equal to a length of the laser region, and the length of the laser region may be larger than or equal to the length of the first amplification region. The current flowing through the laser region, the current flowing through the first amplification region, and the current flowing through the second amplification region can be set to appropriate magnitudes.
(6) An optical apparatus includes a semiconductor laser device; and a feeder configured to be used to apply a voltage to the semiconductor laser device. The semiconductor laser device includes a laser region including an active layer and configured to generate light, an amplification region including the active layer and configured to amplify the light, the amplification region being adjacent to the laser region, and an electrode provided to extend over the laser region and the amplification region. The feeder is electrically connected to the electrode. A voltage is applied to the laser region and the amplification region through the electrode from the feeder, and current is injected. Since the electrode covers the active layer of the laser region and the amplification region, the absorption of light by the active layer can be reduced. Since the electrodes are provided in the laser region and the amplification region, the leakage current can be reduced.
(7) In (6), The optical apparatus may include a plurality of wires electrically connected to the feeder and the electrode. At least one of the plurality of wires may be connected to a portion of the electrode, the portion being provided in the laser region. At least another one of the plurality of wires may be connected to a portion of the electrode, the portion being provided in the amplification region. By using a plurality of wires, the current and voltage can be increased.
(8) A method of controlling a semiconductor laser device is a method of controlling a semiconductor laser device, the semiconductor laser device including a laser region including an active layer and configured to generate light, an amplification region including the active layer and configured to amplify the light, the amplification region being adjacent to the laser region, and an electrode provided to extend over the laser region and the amplification region. The method includes applying an identical voltage to the laser region and the amplification region by using the electrode. A voltage is applied to the laser region and the amplification region using the electrodes to inject current. Since the electrode covers the active layer of the laser region and the amplification region, the absorption of light by the active layer can be reduced. Since the electrodes are provided in the laser region and the amplification region, the leakage current can be reduced.

### DETAILS OF EMBODIMENTS OF PRESENT DISCLOSURE

Specific examples of a semiconductor laser device, an optical apparatus, and a method of controlling a semiconductor laser device according to embodiments of the present disclosure will be described below with reference to the drawings. The present disclosure is not limited to these examples, and is defined by the scope of the claims, and is intended to include all modifications within the meaning and scope equivalent to the scope of the claims.

### First Embodiment

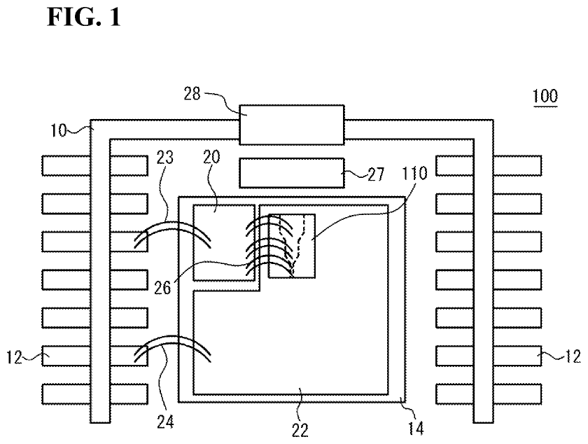

FIG. 1 is a plan view illustrating an optical apparatus 100 according to a first embodiment. Optical apparatus 100 includes an outer wall 10, a pin 12, a submount 14, and a semiconductor laser device 110.

As shown in FIG. 1, outer wall 10 surrounds submount 14 and internally houses submount 14. A lid may be provided on outer wall 10. A plurality of pins 12 are inserted into outer wall 10. A part of pin 12 protrudes outside outer wall 10 and another part protrudes inside outer wall 10. A plurality of pins 12 are spaced apart from each other.

A feeder 20 and a feeder 22 are provided on the upper surface of submount 14. Feeder 20 and feeder 22 are planar electrodes and are spaced apart from each other. Feeder 20 is, for example, an anode. Feeder 22 is, for example, a cathode. Feeder 20 and one of the plurality of pins 12 are electrically connected by a bonding wire 23. Feeder 22 and another one of the plurality of pins 12 are electrically connected by a bonding wire 24.

Semiconductor laser device 110 is provided on the upper surface of feeder 22. The electrodes of semiconductor laser device 110 and feeder 20 are electrically connected by a plurality of bonding wires 26.

An optical component 27 is disposed between outer wall 10 and submount 14. Optical component 27 includes, for example, an isolator and a lens. An optical component 28 is provided on outer wall 10. Optical component 28 is, for example, a lens. Optical component 27 is located between optical component 28 and semiconductor laser device 110, and faces optical component 28 and semiconductor laser device 110. Light emitted from semiconductor laser device 110 enters optical component 27 and optical component 28.

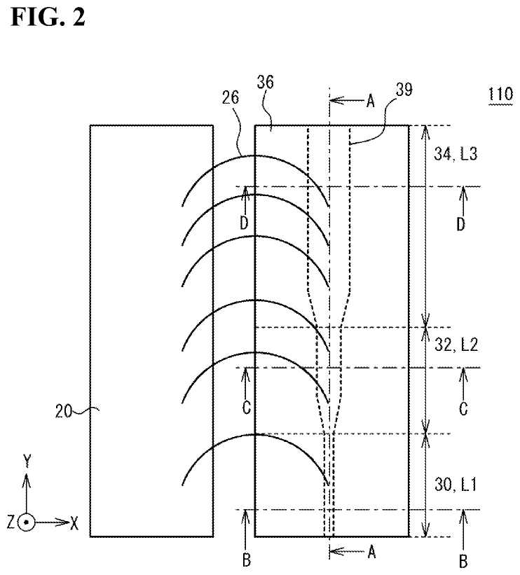

FIG. 2 is a plan view illustrating semiconductor laser device 110. The X-axis direction is a direction crossing semiconductor laser device 110. The Y-axis direction is a direction in which light propagates. The Z-axis direction is a direction in which semiconductor layers are stacked. The X-axis direction, the Y-axis direction, and the Z-axis direction are orthogonal to each other.

As shown in FIG. 2, semiconductor laser device 110 includes a laser region 30, an SOA region 32 (first amplification region), and an SOA region 34 (second amplification region). Laser region 30 functions as a DFB laser element. SOA region 32 and SOA region 34 function as semiconductor optical amplifiers. Laser region 30, SOA region 32, and SOA region 34 are arranged in this order. The length of laser region 30 in the Y-axis direction is L1. The length of SOA region 32 is L2. The length of SOA region 34 is L3.

Semiconductor laser device 110 includes a mesa 39. Mesa 39 extends from laser region 30 to SOA region 32 and SOA region 34 along the Y axis direction. Mesa 39 extends from one end of semiconductor laser device 110 to the other end in the Y-axis direction.

An electrode 36 is formed on the entire upper surface of semiconductor laser device 110, and is provided in laser region 30, SOA region 32, and SOA region 34. One electrode 36 is provided from laser region 30 to SOA region 34 and extends from one end to the other end of semiconductor laser device 110 in the Y-axis direction. Laser region 30, SOA region 32, and SOA region 34 are electrically connected to the common electrode 36. Bonding wire 26 is connected to each of a portion of electrode 36 provided in laser region 30, a portion of electrode 36 provided in SOA region 32, and a portion of electrode 36 provided in SOA region 34.

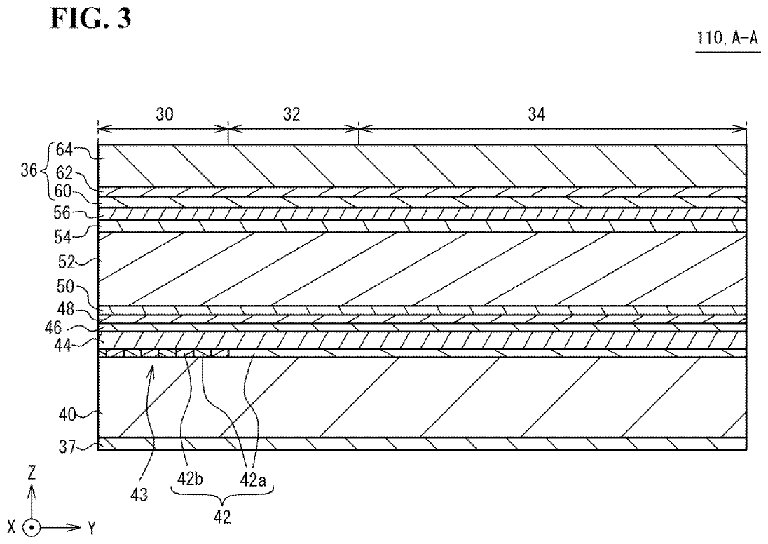

FIG. 3 is a cross-sectional view taken along line A-A of FIG. 2 and illustrates an XZ cross-section of semiconductor laser device 110. Semiconductor laser device 110 includes a substrate 40, a diffraction grating layer 42, a cladding layer 44, an optical confinement layer 46, an active layer 48, an optical confinement layer 50, a cladding layer 52 (second cladding layer), an indium gallium arsenide phosphide (GaInAsP) layer 54, and a contact layer 56. These semiconductor layers are provided continuously in laser region 30, SOA region 32, and SOA region 34.

Diffraction grating layer 42 and cladding layer 44 are stacked on substrate 40 in this order. Substrate 40 and cladding layer 44 function as a first cladding layer. Optical confinement layer 46, active layer 48, optical confinement layer 50, and cladding layer 52 are stacked on cladding layer 44 in this order. GaInAsP layer 54 and contact layer 56 are stacked on cladding layer 52 in this order.

Diffraction grating layer 42 includes a GaInAsP layer 42a and an indium phosphide (InP) layer 42b. GaInAsP layer 42a is provided in SOA region 32 and SOA region 34, but InP layer 42b is not provided therein. In laser region 30, a plurality of GaInAsP layers 42a and a plurality of InP layers 42b are periodically and alternately arranged along the Y-axis direction. GaInAsP layer 42a has a refractive index different from the refractive index of InP layer 42b. A portion where the plurality of GaInAsP layers 42a and the plurality of InP layers 42b are arranged functions as a diffraction grating 43.

Electrode 36 is provided on the upper surface of contact layer 56. Electrode 36 includes three metal layers 60, 62, and 64. Metal layer 60 is in contact with the upper surface of contact layer 56. Metal layer 62 and metal layer 64 are stacked on metal layer 60 in this order. An electrode 37 is provided on the lower surface of substrate 40. Electrode 37 is electrically connected to substrate 40 and is electrically connected to feeder 22 of FIG. 1.

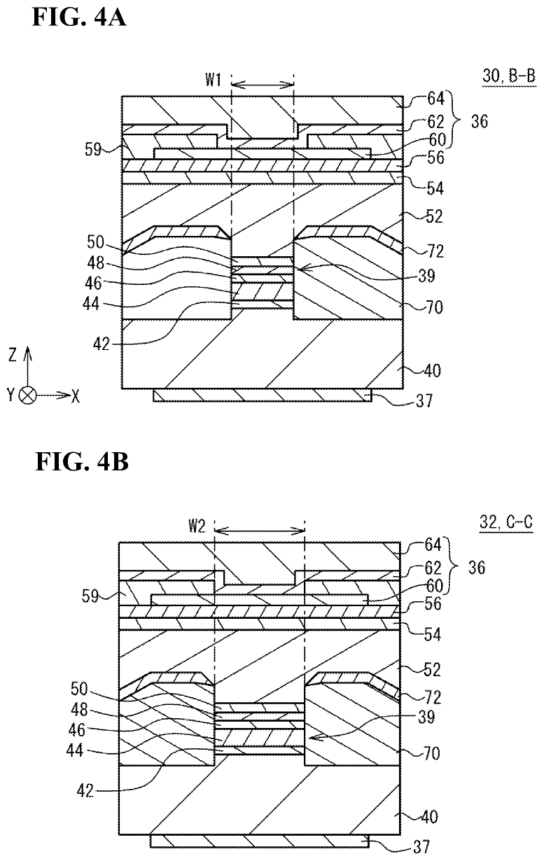

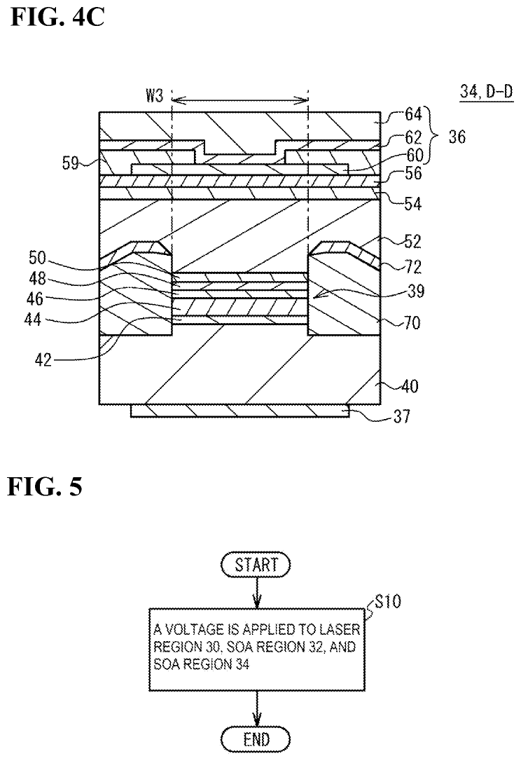

FIGS. 4A to 4C are cross-sectional views illustrating semiconductor laser device 110. FIG. 4A is a cross-sectional view taken along line B-B of FIG. 2 and illustrates a cross-section through laser region 30. FIG. 4B is a cross-sectional view taken along line C-C of FIG. 2 and illustrates a cross-section in SOA region 32. FIG. 4C is a cross-sectional view taken along line D-D of FIG. 2 and illustrates a cross-section through SOA region 34.

As shown in FIGS. 4A-4C, substrate 40, diffraction grating layer 42, cladding layer 44, optical confinement layer 46, active layer 48, and optical confinement layer 50 form mesa 39. A central portion of substrate 40 in the X-axis direction protrudes upward compared with the other portions of substrate 40. Cladding layer 44, optical confinement layer 46, active layer 48, and optical confinement layer 50 are stacked on the protruding portion to form mesa 39. Mesa 39 is located around the center of semiconductor laser device 110 in the X-axis direction.

Semiconductor layers 70 are provided on both sides of mesa 39 in the X-axis direction and on substrate 40, and is not provided on mesa 39. Semiconductor layers 72 are provided on semiconductor layers 70 and on both sides of mesa 39, and is not provided on mesa 39. Cladding layer 52 is provided on mesa 39 and on semiconductor layers 72.

Metal layer 60 of electrode 36 is provided above mesa 39 on the upper surface of contact layer 56, and is electrically connected to contact layer 56. An electrically insulating film 59 is provided on a part of the upper surface of contact layer 56 and a part of the upper surface of metal layer 60. Electrically insulating film 59 has an opening on a central portion of metal layer 60. The central portion of metal layer 60 is not covered by electrically insulating film 59. Metal layer 62 is provided on the upper surface of electrically insulating film 59 and the upper surface of metal layer 60.

Substrate 40 and cladding layer 44 are formed of, for example, n-type indium phosphide (n-InP). Silicon (Si) is added as a dopant to the n-type semiconductor layer.

Semiconductor layer 70 is formed of, for example, p-type indium phosphide (p-InP). Zinc (Zn) is added as a dopant to the p-type semiconductor layer. Semiconductor layer 70 is formed by stacking, for example, two p-InP layers. The lower one of the two p-InP layers has, for example, a Zn concentration of 1×10¹⁸ cm⁻³ and a thickness of 200 nm. The upper one of the two p-InP layers has a Zn concentration of 5×10¹⁷ cm⁻³, and a thickness of 1100 nm. The upper one of the two p-InP layer of semiconductor layer 70 is grown by adding chlorine (CI).

Semiconductor layer 72 is formed by stacking, for example, two n-InP layers. The lower one of the two n-InP layers has, for example, a Si concentration of 1×10¹⁹ cm⁻³ and a thickness of 200 nm. The upper one of the two n-InP layers has a Si concentration of 1×10¹⁹ cm⁻³ and a thickness of 300 nm. The lower one of the two n-InP layers of semiconductor layer 72 is grown by adding Cl.

Active layer 48, optical confinement layer 46, and optical confinement layer 50 form a separate confinement heterostructure (SCH) structure. Active layer 48 has a multi-quantum well (MQW) structure and includes a plurality of well layers and a plurality of barrier layers. The plurality of well layers and the plurality of barrier layers are alternately stacked. The well layer and the barrier layer are formed of, for example, gallium indium arsenide phosphide (GaInAsP). Optical confinement layer 46 and optical confinement layer 50 are formed of, for example, GaInAsP. The refractive indices of optical confinement layer 46 and optical confinement layer 50 are lower than the refractive index of active layer 48 and higher than the refractive indices of cladding layer 44 and cladding layer 52.

Cladding layer 52 is formed of, for example, p-InP, and is formed by stacking three p-InP layers. The lower one of the three p-InP layers has a Zn concentration of 5.0×10¹⁷ cm⁻³ and a thickness of 200 nm, for example. The middle one of the three p-InP layers has, for example, a Zn concentration of 1.0×10¹⁸ cm⁻³ and a thickness of 500 nm. The upper one of the three p-InP layers has, for example, a Zn concentration of 2.0×10¹⁸ cm⁻³ and a thickness of 2500 nm.

GaInAsP layer 54 is formed by stacking two p-GaInAsP layers. The lower one of the two p-GaInAsP layers has a Zn concentration of 2×10¹⁸ cm⁻³, a thickness of 50 nm, and a bandgap of 1.1 μm. The upper one of the two p-GaInAsP layers has a Zn concentration of 2×10¹⁸ cm⁻³, a thickness of 100 nm, and a bandgap of 1.2 μm. Contact layer 56 is formed of, for example, p-InGaAs. The thickness is 500 nm. The semiconductor layers of semiconductor laser device 110 may be formed of compound semiconductors other than those described above.

Electrically insulating film 59 is formed of an insulator such as silicon nitride (SiN). Metal layer 60 of electrode 36 is formed by stacking, for example, a gold (Au) layer, a Zn layer, and an Au layer in this order. Metal layer 62 is formed by stacking, for example, a titanium (Ti) layer and a tungsten (W) layer in this order. The thickness of metal layer 62 is, for example, 0.1 μm. Metal layer 64 is formed of, for example, Au and is manufactured by plating. The thickness of metal layer 64 is, for example, 3 μm. Electrode 37 is made of, for example, metal.

As shown in FIG. 4A, the width in the X-axis direction of mesa 39 in laser region 30 is W1. As shown in FIG. 4B, the width of mesa 39 in SOA region 32 is W2. As shown in FIG. 4C, the width of mesa 39 in SOA region 34 is W3. A width W1 is less than or equal to a width W2. Width W2 is less than or equal to a width W3. As shown in FIG. 2, mesa 39 has a tapered shape between laser region 30 and SOA region 32 and between SOA region 32 and SOA region 34. That is, the width of mesa 39 changes continuously.

### (Method of Controlling)

FIG. 5 is a flow chart illustrating the method of controlling semiconductor laser device 110. An identical voltage is applied from feeders 20 and 22 of optical apparatus 100 to laser region 30, SOA region 32, and SOA region 34 of semiconductor laser device 110 (step S10). The current flows through each region. Laser region 30 emits light. SOA region 32 and SOA region 34 amplify light. Then, the processing of FIG. 5 ends.

As shown in FIG. 2, feeder 20 is electrically connected to electrode 36 by bonding wire 26. Feeder 22 is electrically connected to electrode 37. A positive voltage is applied from feeder 20 to electrode 36. A negative voltage is applied from feeder 22 to electrode 37. A DC voltage is applied to semiconductor laser device 110.

A p-type cladding layer 52, n-type semiconductor layers 72, and p-type semiconductor layers 70 are stacked on both sides of mesa 39. Therefore, the current hardly flows outside mesa 39. P-type cladding layer 52 is provided above active layer 48, and an n-type cladding layer 44 and substrate 40 are provided below active layer 48. The current is confined by the buried structures on both sides of mesa 39 and selectively flows through mesa 39.

The current flows through mesa 39. Carriers are injected into and coupled with active layer 48 to generate light. The light is laser-oscillated at a wavelength corresponding to the period of diffraction grating 43. Light enters SOA region 32 from laser region 30, and further enters SOA region 34. The light is amplified in SOA region 32 and SOA region 34. The amplified light is emitted from the end of SOA region 34 to the outside of semiconductor laser device 110. The light is transmitted through optical component 27 and optical component 28 of optical apparatus 100 to be emitted.

### (Method of Manufacturing)

Diffraction grating layer 42, cladding layer 44, optical confinement layer 46, active layer 48, and optical confinement layer 50 are epitaxially grown in this order on the upper surface of substrate 40 by, for example, metal organic chemical vapor deposition (MOCVD). Etching is performed to form mesa 39. The width of mesa 39 in each region is controlled by adjusting the shape of the etching mask.

After mesa 39 is formed, semiconductor layers 70 and semiconductor layers 72 are epitaxially grown on both sides of mesa 39. Cladding layer 52, GaInAsP layer 54, and contact layer 56 are epitaxially grown on mesa 39 and semiconductor layers 72. For example, metal layer 60 is formed by vacuum deposition. Electrically insulating film 59 is formed by a plasma CVD method. Metal layer 62 is formed by vacuum deposition. Plating is performed to form metal layer 64. Electrode 37 is formed on the lower surface of substrate 40. Through the above steps, semiconductor laser device 110 is formed.

For example, electrode 37 of semiconductor laser device 110 is fixed to the surface of feeder 22 of optical apparatus 100 by soldering. Electrode 36 and feeder 20 are connected by a plurality of bonding wires 26. Semiconductor laser device 110 is mounted on optical apparatus 100.

### Comparative Example

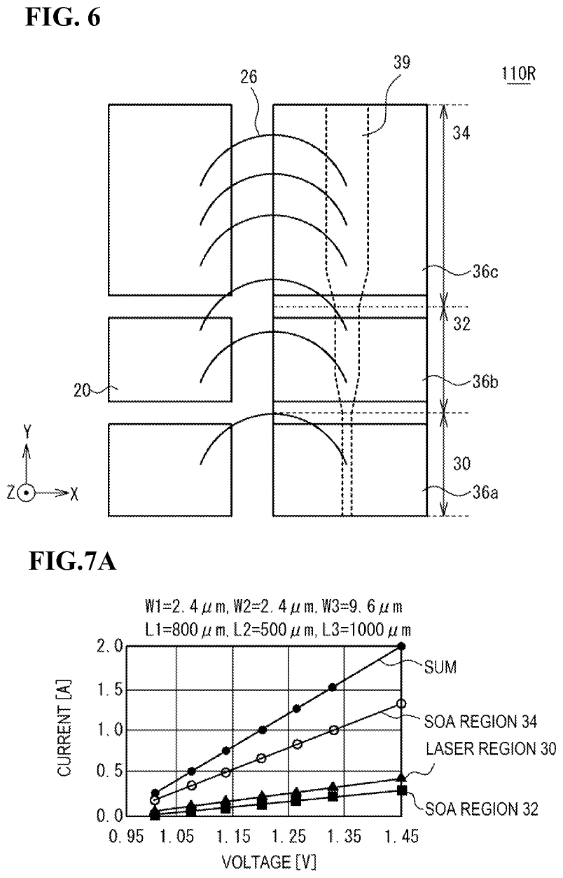

FIG. 6 is a plan view illustrating a semiconductor laser device 110R according to a comparative example. Semiconductor laser device 110R has three electrodes 36a, 36b, and 36c. Electrode 36a is provided in laser region 30. Electrode 36b is provided in SOA region 32. Electrode 36c is provided in SOA region 34. Electrodes 36a, 36b, and 36c are spaced apart from one another. In mesa 39, no electrode is provided between electrode 36a and electrode 36b and between electrode 36b and electrode 36c.

A feeder 20a, a feeder 20b, and a feeder 20c are spaced from each other. Feeder 20a is electrically connected to electrode 36a. Feeder 20b is electrically connected to electrode 36b. Feeder 20c is electrically connected to electrode 36c. A voltage is applied to laser region 30, SOA region 32, and SOA region 34 independently of each other.

The current is injected into the portion of mesa 39 where the electrode is provided. No current is injected into the portion of mesa 39 where no electrode is provided. In a portion of mesa 39 where no electrode is provided, active layer 48 absorbs light more easily than in a portion where an electrode is provided. The absorption of light results in the loss of light. The optical output obtained with respect to the input power decreases, and the efficiency decreases. By reducing the distance between the electrodes, the absorption of light can be reduced. However, by reducing the distance, the insulation resistance between the electrodes is reduced. The leakage current easily flows between the electrodes. As the leakage current increases, power is lost and efficiency is reduced.

In the first embodiment, as shown in FIGS. 2 and 3, one electrode 36 is provided in laser region 30, SOA region 32, and SOA region 34. Electrode 36 is provided above the whole of mesa 39. Since the current is injected into the whole of active layer 48, active layer 48 hardly absorbs light. Since electrode 36 is not divided, the leakage current hardly flows. Since the loss of light and the loss of power are reduced as compared with the comparative example, the efficiency is increased.

The same voltage is applied to laser region 30, SOA region 32, and SOA region 34 using electrode 36. On the other hand, the current flowing through laser region 30, the current flowing through SOA region 32, and the current flowing through SOA region 34 may be different from each other.

The current depends on the electrical resistance. The electrical resistance is determined by the width of mesa 39 and the length of the region. For example, width W1 of mesa 39 in laser region 30 is equal to or less than width W2 in SOA region 32 and width W3 in SOA region 34. Width W2 in SOA region 32 is equal to or less than width W3 in SOA region 34. By adjusting the width and the length, the current flowing through each region can be set to an appropriate magnitude.

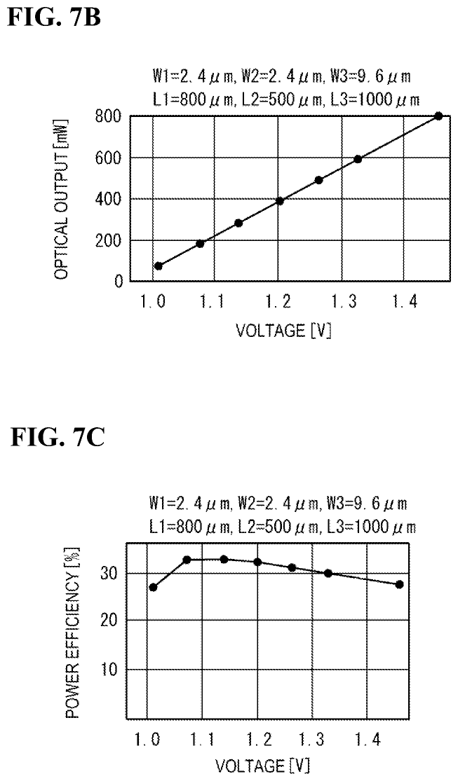

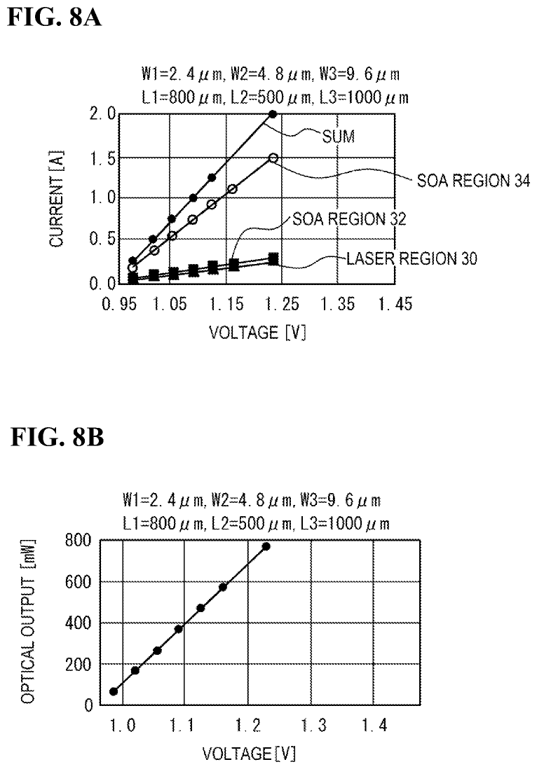

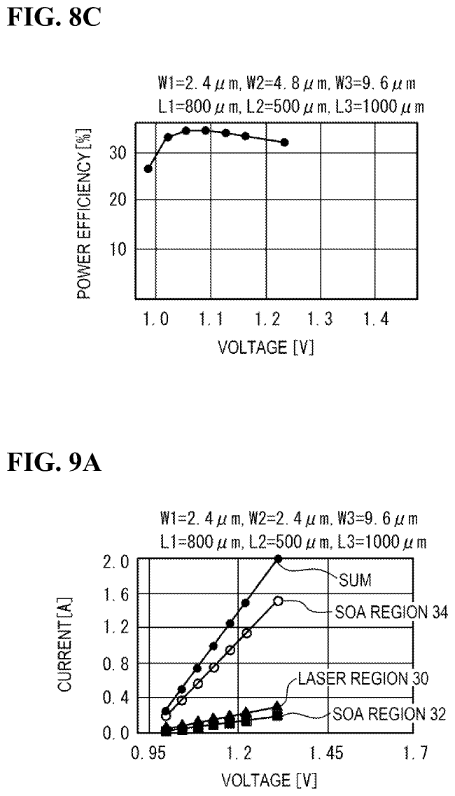

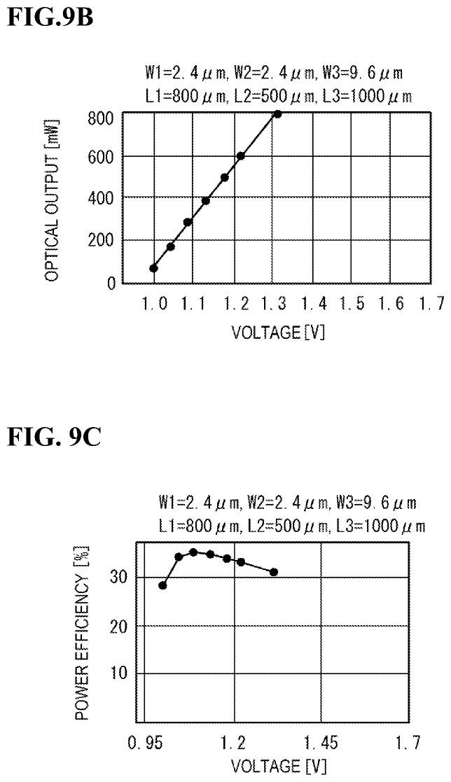

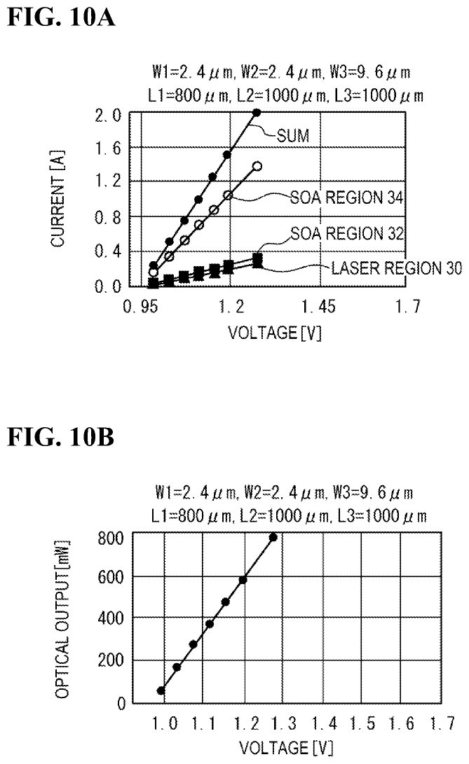

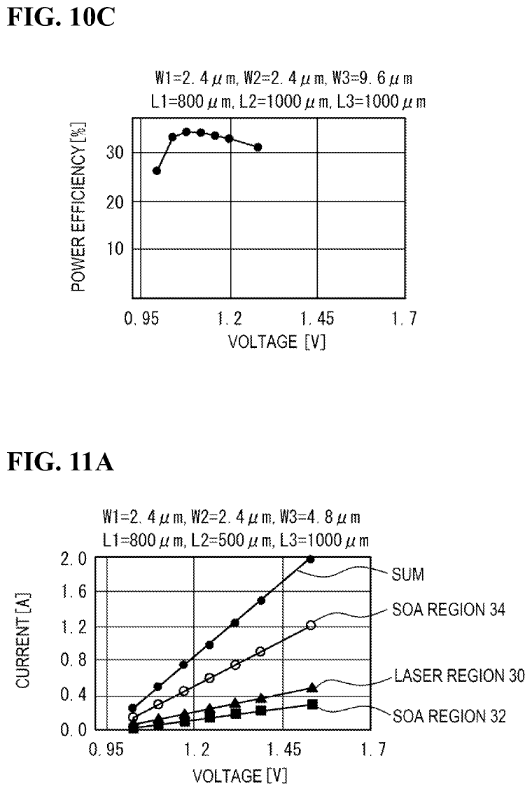

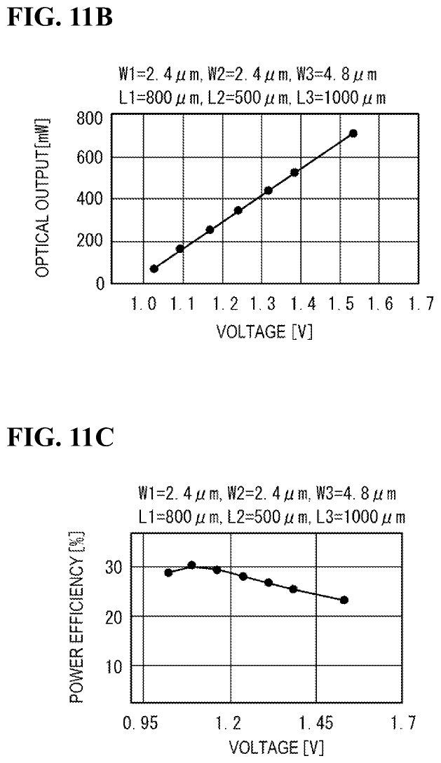

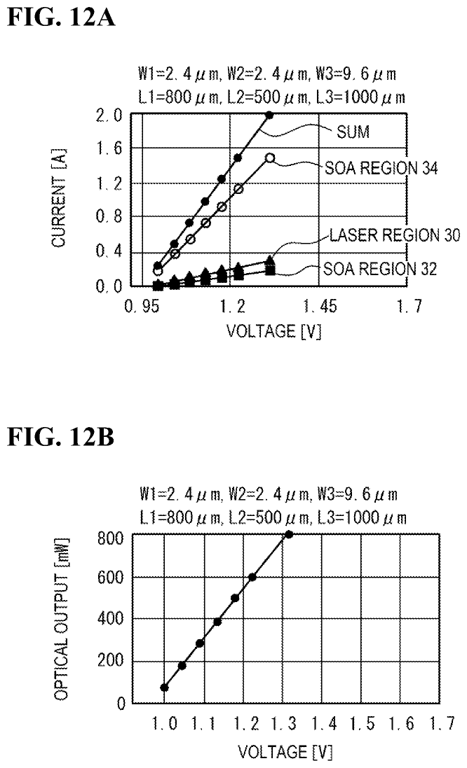

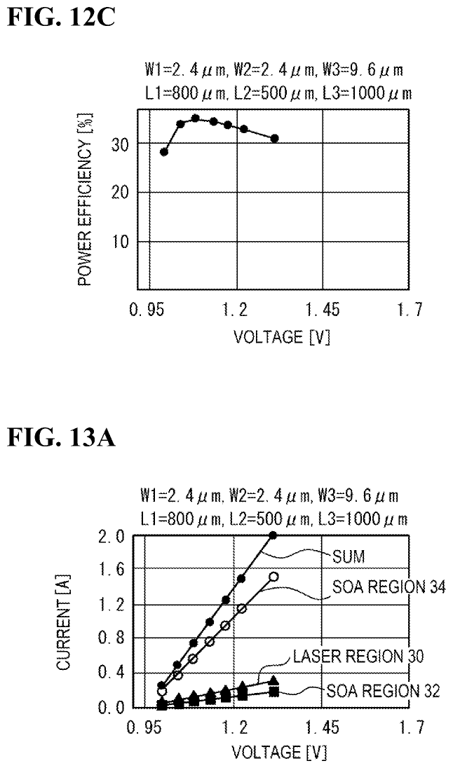

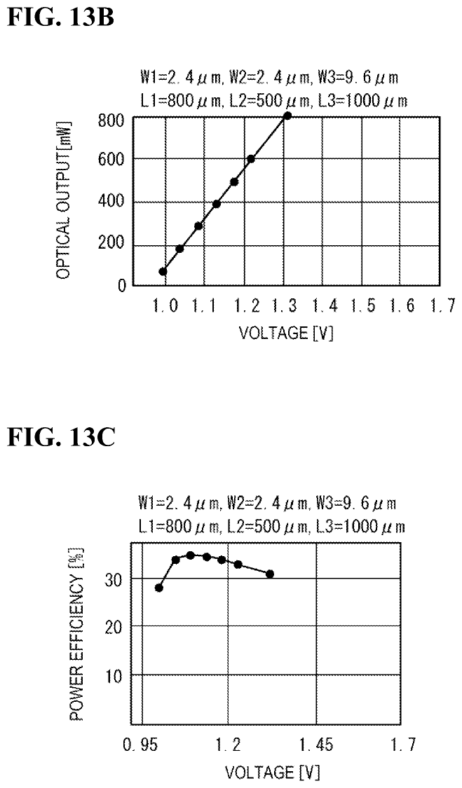

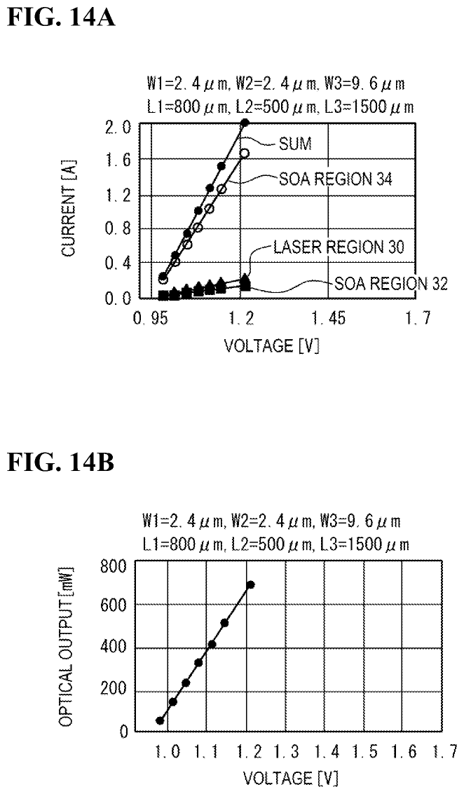

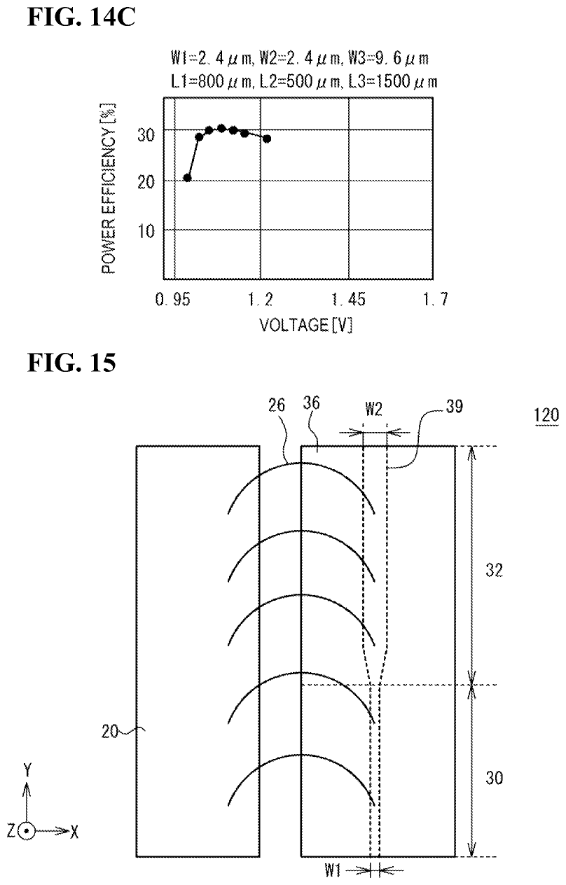

FIGS. 7A to 14C are diagrams illustrating the characteristics of semiconductor laser device 110, showing the calculated result of current, optical output and power efficiency. FIG. 7A, FIG. 8A, FIG. 9A, FIG. 10A, FIG. 11A, FIG. 12A, FIG. 13A and FIG. 14A are diagrams illustrating current. The vertical axis represents the current. Triangles represent the current flowing through laser region 30. Squares represent the current flowing through SOA region 32. White circles represent the current flowing through SOA region 34. Black circles represent the sum of the currents flowing in each region. FIG. 7B, FIG. 8B, FIG. 9B, FIG. 10B, FIG. 11B, FIG. 12B, FIG. 13B and FIG. 14B are diagrams illustrating optical output. The vertical axis represents the optical output. FIG. 7C, FIG. 8C, FIG. 9C, FIG. 10C, FIG. 11C, FIG. 12C, FIG. 13C and FIG. 14C are diagrams illustrating power efficiency. The vertical axis represents the power efficiency. The horizontal axis of each of FIGS. 7A to 14C represents the voltage applied to semiconductor laser device 110.

In the example of FIGS. 7A to 7C, width W1 of mesa 39 in laser region 30 is 2.4 μm. Width W2 of mesa 39 in SOA region 32 is 2.4 μm. Width W3 of mesa 39 in SOA region 34 is 9.6 μm. A length L1 of laser region 30 is 800 μm. A length L2 of SOA region 32 is 500 μm. A length L3 of SOA region 34 is 1000 μm. The current flowing through laser region 30 is larger than the current flowing through SOA region 32. The current flowing through SOA region 34 is larger than the current flowing through laser region 30. When the voltage is 1.0 V, the optical output is about 100 mW. When the voltage is increased, the optical output rises to 800 mW. The power efficiency is around 30%.

In the example of FIGS. 8A to 8C, width W1 of mesa 39 in laser region 30 is 2.4 μm. Width W2 of mesa 39 in SOA region 32 is 4.8 μm. Width W3 of mesa 39 in SOA region 34 is 9.6 μm. Length L1 of laser region 30 is 800 μm. Length L2 of SOA region 32 is 500 μm. Length L3 of SOA region 34 is 1000 μm. Width W2 in the example of FIGS. 8A to 8C is larger than in the example of FIGS. 7A to 7C. The electrical resistance of SOA region 32 is reduced. The current flowing through SOA region 32 is larger than the current flowing through laser region 30. At the same voltage, the optical output shown in FIG. 8B is larger than the optical output of FIG. 7B. The power efficiency shown in FIG. 8C is larger than the power efficiency shown in FIG. 7C.

In the example of FIGS. 9A to 9C, width W1 of mesa 39 in laser region 30 is 2.4 μm. Width W2 of mesa 39 in SOA region 32 is 2.4 μm. Width W3 of mesa 39 in SOA region 34 is 9.6 μm. Length L1 of laser region 30 is 800 μm. Length L2 of SOA region 32 is 500 μm. Length L3 of SOA region 34 is 1000 μm. The current flowing through laser region 30 is larger than the current flowing through SOA region 32. The current flowing through SOA region 34 is larger than the current flowing through laser region 30. When the voltage is increased, the optical output rises to 800 mW. The power efficiency is around 30%.

In the example of FIGS. 10A to 10C, width W1 of mesa 39 in laser region 30 is 2.4 μm. Width W2 of mesa 39 in SOA region 32 is 2.4 μm. Width W3 of mesa 39 in SOA region 34 is 9.6 μm. Length L1 of laser region 30 is 800 μm. Length L2 of SOA region 32 is 1000 μm. Length L3 of SOA region 34 is 1000 μm. Length L2 in the example of FIGS. 10A to 10C is larger than in the example of FIGS. 9A to 9C. The electrical resistance of SOA region 32 is reduced. The current flowing through SOA region 32 is larger than the current flowing through laser region 30. The optical output varies from below 100 mW to 800 mW. The power efficiency is around 30%.

In the example of FIGS. 11A to 11C, width W1 of mesa 39 in laser region 30 is 2.4 μm. Width W2 of mesa 39 in SOA region 32 is 2.4 μm. Width W3 of mesa 39 in SOA region 34 is 4.8 μm. Length L1 of laser region 30 is 800 μm. Length L2 of SOA region 32 is 500 μm. Length L3 of SOA region 34 is 1000 μm. The current flowing through laser region 30 is larger than the current flowing through SOA region 32. The current flowing through SOA region 34 is larger than the current flowing through laser region 30. The optical output varies from below 100 mW to about 700 mW. The power efficiency is around 30%.

In the example of FIGS. 12A to 12C, width W1 of mesa 39 in laser region 30 is 2.4 μm. Width W2 of mesa 39 in SOA region 32 is 2.4 μm. Width W3 of mesa 39 in SOA region 34 is 9.6 μm. Length L1 of laser region 30 is 800 μm. Length L2 of SOA region 32 is 500 μm. Length L3 of SOA region 34 is 1000 μm. Width W3 in the example of FIGS. 12A to 12C is larger than in the example of FIGS. 11A to 11C. The electrical resistance of SOA region 34 is reduced. When compared at the same voltage, the current flowing through SOA region 34 shown in FIG. 12A is larger than the current shown in FIG. 11A. The optical output shown in FIG. 12B is larger than the optical output shown in FIG. 11B. The power efficiency shown in FIG. 12C is larger than the power efficiency shown in FIG. 11C.

In the example of FIGS. 13A to 13C, width W1 of mesa 39 in laser region 30 is 2.4 μm. Width W2 of mesa 39 in SOA region 32 is 2.4 μm. Width W3 of mesa 39 in SOA region 34 is 9.6 μm. Length L1 of laser region 30 is 800 μm. Length L2 of SOA region 32 is 500 μm. Length L3 of SOA region 34 is 1000 μm. The current flowing through laser region 30 is larger than the current flowing through SOA region 32. The current flowing through SOA region 34 is larger than the current flowing through laser region 30. The optical output varies from below 100 mW to 800 mW. The power efficiency is 20% or more, and when the voltage becomes high, the power efficiency becomes around 30%.

In the example of FIGS. 14A to 14C, width W1 of mesa 39 in laser region 30 is 2.4 μm. Width W2 of mesa 39 in SOA region 32 is 2.4 μm. Width W3 of mesa 39 in SOA region 34 is 9.6 μm. Length L1 of laser region 30 is 800 μm. Length L2 of SOA region 32 is 500 μm. Length L3 of SOA region 34 is 1500 μm. Length L3 in the example of FIGS. 14A to 14C is larger than in the example of FIGS. 13A to 13C. The electrical resistance of SOA region 34 is reduced. When compared at the same voltage, the current flowing through SOA region 34 shown in FIG. 14A is larger than the current shown in FIG. 13A. The optical output shown in FIG. 14B is larger than the optical output shown in FIG. 13B. The power efficiency is 20% or more, and when the voltage becomes high, the power efficiency becomes around 30%.

According to the first embodiment, semiconductor laser device 110 includes laser region 30, SOA region 32, and SOA region 34. SOA region 32 is adjacent to and optically coupled to laser region 30. SOA region 34 is adjacent to and optically coupled to SOA region 32. Electrode 36 is provided to extend from laser region 30 to SOA region 32 and SOA region 34. A voltage is applied to laser region 30, SOA region 32, and SOA region 34 using electrode 36. The whole region over active layer 48 is covered by electrode 36 and the current is injected. Since active layer 48 hardly absorbs light, the loss of light is reduced. Since electrode 36 extends from laser region 30 to SOA region 34, the leakage current generated between the electrodes is reduced. The loss of power is reduced. The efficiency of semiconductor laser device 110 is improved.

The identical voltage is applied to laser region 30, SOA region 32, and SOA region 34 using electrode 36. Depending on the width and length of mesa 39, the electrical resistance of each region is determined and the flowing current varies. The current flowing through laser region 30, the current flowing through SOA region 32, and the current flowing through SOA region 34 are set to appropriate magnitudes. Light may be generated in laser region 30. Light can be amplified in SOA region 32 and SOA region 34.

As in the example of FIGS. 7A to 14C, width W3 of mesa 39 in SOA region 34 is larger than or equal to width W2 in SOA region 32 and width W1 in laser region 30, and may be, for example, twice or more, three times or more, or four times or more of widths W1 and W2. The electrical resistance of SOA region 34 per unit length is lower than the electrical resistance of SOA region 32 and the electrical resistance of laser region 30. The current flowing through SOA region 34 is larger than the current flowing through SOA region 32 and the current flowing through laser region 30.

Width W2 of SOA region 32 is larger than or equal to width W1 of laser region 30, and may be, for example, twice or more of width W1. The electrical resistance of SOA region 32 per unit length is lower than the electrical resistance of laser region 30. Width W2 in SOA region 32 may be equal to width W1 in laser region 30.

The electrical resistance of each region depends on the width of mesa 39 and also on the length of mesa 39. Length L3 of SOA region 34 is larger than or equal to length L1 of laser region 30 and length L2 of SOA region 32, and may be, for example, twice or more, or three times or more of length L2. Length L3 may be equal to length L2. Length L1 of laser region 30 may be larger than or equal to length L2 of SOA region 32.

Optical apparatus 100 shown in FIG. 1 includes feeder 20 and feeder 22. Feeder 22 is connected to electrode 37 of semiconductor laser device 110. As shown in FIG. 2, feeder 20 is connected to electrode 36 of semiconductor laser device 110 by bonding wire 26. Electrode 36 is not divided corresponding to the regions, and is provided in laser region 30, SOA region 32, and SOA region 34. Feeder 20 is also not divided corresponding to the regions. The structure of optical apparatus 100 is simplified. One feeder 20 and one electrode 36 are connected. The common voltage is applied to laser region 30, SOA region 32, and SOA region 34. By changing the width of mesa 39, the current can be set to an optimum value for each region.

A plurality of bonding wires 26 are connected to feeder 20 and electrode 36. At least one of bonding wires 26 is connected to a portion of electrode 36 provided in laser region 30. At least one of bonding wires 26 is connected to a portion of electrode 36 provided in SOA region 32. At least one of bonding wires 26 is connected to a portion of electrode 36 provided in SOA region 34. By using a plurality of bonding wires 26, the current and voltage can be increased. For example, the current may be 1 A or more and the voltage may be 1 V or more.

### Second Embodiment

FIG. 15 is a plan view illustrating a semiconductor laser device 120 according to a second embodiment. Description of the same configuration as that of the first embodiment will be omitted.

As shown in FIG. 15, semiconductor laser device 120 has laser region 30 and SOA region 32. SOA region 32 is adjacent to laser region 30. Mesa 39 extends from laser region 30 to SOA region 32. Electrode 36 is provided in laser region 30 and SOA region 32. Feeder 20 is electrically connected to electrode 36 by bonding wire 26. Width W2 of mesa 39 in SOA region 32 is larger than or equal to width W1 of mesa 39 in laser region 30.

According to the second embodiment, electrode 36 is provided in laser region 30 and SOA region 32. The current is injected into the whole of active layer 48 of semiconductor laser device 120. Since active layer 48 hardly absorbs light, the loss of light is reduced. Since electrode 36 extends from laser region 30 to SOA region 32, the leakage current generated between the electrodes is reduced. The loss of power is reduced. The efficiency of semiconductor laser device 120 is improved.

The identical voltage is applied to laser region 30 and SOA region 32 using electrode 36. Width W2 of mesa 39 in SOA region 32 is larger than or equal to width W1 of mesa 39 in laser region 30. Depending on the width of mesa 39, the electrical resistance of each region is determined and the flowing current also changes. The magnitude of the current can be optimized. Light may be generated in laser region 30 and amplified in SOA region 32.

### Third Embodiment

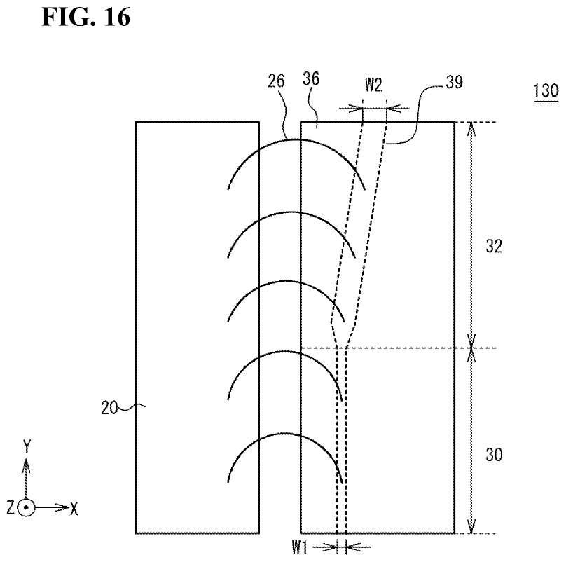

FIG. 16 is a plan view illustrating a semiconductor laser device 130 according to a third embodiment. Description of the same configuration as that of either the first embodiment or the second embodiment will be omitted.

As shown in FIG. 16, semiconductor laser device 120 has laser region 30 and SOA region 32. Mesa 39 extends parallel to the Y-axis direction in laser region 30, and extends at an angle from the Y-axis direction in SOA region 32. Electrode 36 is provided in laser region 30 and SOA region 32. Feeder 20 is electrically connected to electrode 36 by bonding wire 26. Width W2 of mesa 39 in SOA region 32 is larger than or equal to width W1 of mesa 39 in laser region 30.

According to the third embodiment, electrode 36 is provided in laser region 30 and SOA region 32. The absorption of light and the leakage current are reduced. The loss of power is reduced. The efficiency of semiconductor laser device 130 is improved.

The identical voltage is applied to laser region 30 and SOA region 32 using electrode 36. Width W2 of mesa 39 in SOA region 32 is larger than or equal to width W1 of mesa 39 in laser region 30. Depending on the width of mesa 39, the electrical resistance of each region is determined and the flowing current also changes. The magnitude of the current can be optimized. Light may be generated in laser region 30 and amplified in SOA region 32.

The semiconductor laser device includes laser region 30 and at least one SOA region. The number of SOA regions may be one, or two or more. Electrode 36 is provided on laser region 30 and the SOA region. By injecting current into active layer 48, light is generated in laser region 30. The SOA region amplifies light. In both laser region 30 and the SOA region, mesa 39 may be parallel to the Y-axis. The light propagates through mesa 39 parallel to the Y-axis direction. In at least one of laser region 30 and the SOA region, mesa 39 may be inclined with respect to the Y-axis.

Although the embodiments of the present disclosure have been described in detail above, the present disclosure is not limited to the specific embodiments, and various modifications and changes can be made within the scope of the gist of the present disclosure described in the claims.

What is claimed is:

1. A semiconductor laser device comprising:
a laser region including an active layer and configured to generate light;
an amplification region including the active layer and configured to amplify the light, the amplification region being adjacent to the laser region; and
an electrode provided to extend over the laser region and the amplification region.

2. The semiconductor laser device according to claim 1,
wherein the laser region and the amplification region include a first cladding layer and a second cladding layer,
wherein the first cladding layer, the active layer, and the second cladding layer are stacked sequentially and form a mesa in the laser region and the amplification region, and
wherein a width of the mesa in the amplification region is larger than or equal to a width of the mesa in the laser region.

3. The semiconductor laser device according to claim 1,
wherein the amplification region includes a first amplification region and a second amplification region,
wherein the laser region and the first amplification region are adjacent to each other,
wherein the first amplification region and the second amplification region are adjacent to each other, and
wherein the electrode is provided in the laser region, the first amplification region, and the second amplification region.

4. The semiconductor laser device according to claim 3,
wherein a width of the mesa in the second amplification region is larger than or equal to a width of the mesa in the first amplification region, and
wherein the width of the mesa in the first amplification region is larger than or equal to a width of the mesa in the laser region.

5. The semiconductor laser device according to claim 3,
wherein a length of the second amplification region is larger than or equal to a length of the first amplification region and is larger than or equal to a length of the laser region, and
wherein the length of the laser region is larger than or equal to the length of the first amplification region.

6. An optical apparatus comprising:
a semiconductor laser device; and
a feeder configured to be used to apply a voltage to the semiconductor laser device,
wherein the semiconductor laser device includes
a laser region including an active layer and configured to generate light,
an amplification region including the active layer and configured to amplify the light, the amplification region being adjacent to the laser region, and
an electrode provided to extend over the laser region and the amplification region, and
wherein the feeder is electrically connected to the electrode.

7. The optical apparatus according to claim 6, further comprising:
a plurality of wires electrically connected to the feeder and the electrode,
wherein at least one of the plurality of wires is connected to a portion of the electrode, the portion being provided in the laser region, and
wherein at least another one of the plurality of wires is connected to a portion of the electrode, the portion being provided in the amplification region.

8. A method of controlling a semiconductor laser device, the semiconductor laser device including
a laser region including an active layer and configured to generate light,
an amplification region including the active layer and configured to amplify the light, the amplification region being adjacent to the laser region, and
an electrode provided to extend over the laser region and the amplification region, the method comprising:
applying an identical voltage to the laser region and the amplification region by using the electrode.
